(19) United States
(12) Patent Application Publication
(10) Pub. No.: US 2002/0145458 A1
(43) Pub. Date: Oct. 10, 2002

(54) Clock-skew resistant chain of sequential cells

(76) Inventors: Frederic Natali, Nice (FR); Laurent Souef, Montauroux (FR)

Correspondence Address: U.S. Philips Corporation, 580 White Plains Road, Tarrytown, NY, 10591, US

(21) Appl. No.: 10/086,851

(22) Filed: Mar. 1, 2002

(30) Foreign Application Priority Data
Mar. 6, 2001 (EP) 01400587.0

(51) Int. Cl. H03H 11/26

(52) U.S. Cl. 327/262

(57) ABSTRACT

In an integrated circuit incorporating a series of sequential cells (SEQ(1)-SEQ(7)) implementing a shift function, clock skew problems are avoided by interconnecting the cells in order starting with the cell (SEQ(3)) having greatest clock latency and ending with the cell (SEQ(7)) having smallest clock latency.

The present invention relates to the field of integrated circuit design and, more particularly, to the design of integrated circuits incorporating a series of sequential cells implementing a shift.

LSI and VLSI integrated circuits often include a series of cells inter-connected to one another so as to form a sort of shift register. Often the data being transferred along the sequence of cells is data collected from a core undergoing test, in which case the series of cells is referred to as a scan chain. For example, boundary scan systems are well-known in which each cell of the scan chain is connected to a respective pin of the integrated circuit, or group of inter-connected integrated circuits, to be tested. In general, the cells consist of flip-flops, with any required associated devices (for example, multiplexers), and can be considered to constitute memory cells. In the case of cells making up a scan chain, each cell also plays a part in the functioning of the integrated circuit(s) to be tested. However, the cells operate in functional and non-functional (scan) modes at different times and the physical paths interconnecting the scan chain cells for implementation of data shift during the scan process are independent of the functional paths.

It is to be understood that the present invention is applicable to any series of sequential cells implementing a shift function; scan chains are merely one example of such series of sequential cells.

In general, all the sequential cells of a series implementing a shift function make use of a common clock signal, running at a different frequency from the system clock. There is often a problem arising due to the fact that the clock path, from the source of the common clock signal to the clock pin of the respective cell, is different for the different cells. Where such a clock path difference (or difference in “clock latency”) exists between two cells, the difference between the longer clock path and the shorter clock path is termed clock skew, and it is a well-known source of problems. For example, in some circumstances clock skew can lead to failure of the shift operation.

In order to overcome the problems arising from clock skew, there has been a proposal to use an asynchronous system, in which the various elements of the series of sequential cells do not use a common clock signal. However, in general, synchronous systems are used and strenuous efforts are made during design of the overall integrated circuit so as to minimize or eradicate clock skew. The designs that are achieved to minimize or eradicate clock skew increase the power consumption of the chip and limit its operating frequency. Moreover, the design time involved in finding these solutions increases the duration and overall costs of the development process.

It is an object of the present invention to provide an integrated circuit comprising a series of sequential cells implementing a shift function, in which the adverse effects caused by clock skew are reduced or eliminated altogether.

It is a further object of the present invention to provide a method of manufacturing an integrated circuit comprising a series of sequential cells implementing a shift function, in which the adverse effects of clock skew are reduced or eliminated

The present inventors have realized that it is not essential to eradicate clock skew. In fact, in certain circumstances clock skew can be beneficial. More particularly, in some cases, clock skew causes the driving cell to have greater clock latency than the following cell in the series (the receiving cell), and this has a positive effect on shift.

The invention takes the following aspects into consideration. In a circuit comprising a series of sequential cells, the lengths of the clock paths between the source of the clock signal and the respective sequential cells are determined. The corresponding cells are interconnected (chained) in an order such that the clock paths associated therewith decrease from one cell to the next in the series.

By accepting clock skew and turning it to advantage, the present invention enables considerable time and costs savings to be made during design, and enables test circuit performance to be improved.

Various stages are involved in the design of integrated circuits. According to preferred embodiments of the present invention, the steps of determining clock path length, and chaining cells in order from longest associated clock path to shortest, take place during the steps of Place&Route and ClockTree generation (this is explained in greater detail below).

The invention and additional features, which may be optionally used to implement the invention to advantage, are apparent from and elucidated with reference to the drawings described hereinafter.

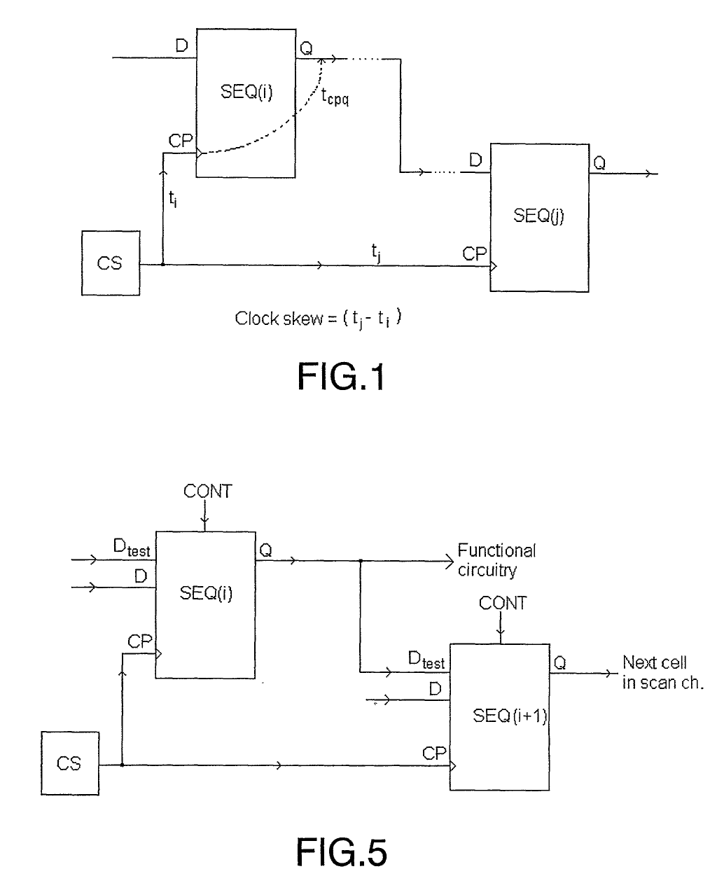

FIG. 1 schematically represents clock paths for two cells in a series of sequential cells implementing a shift function;

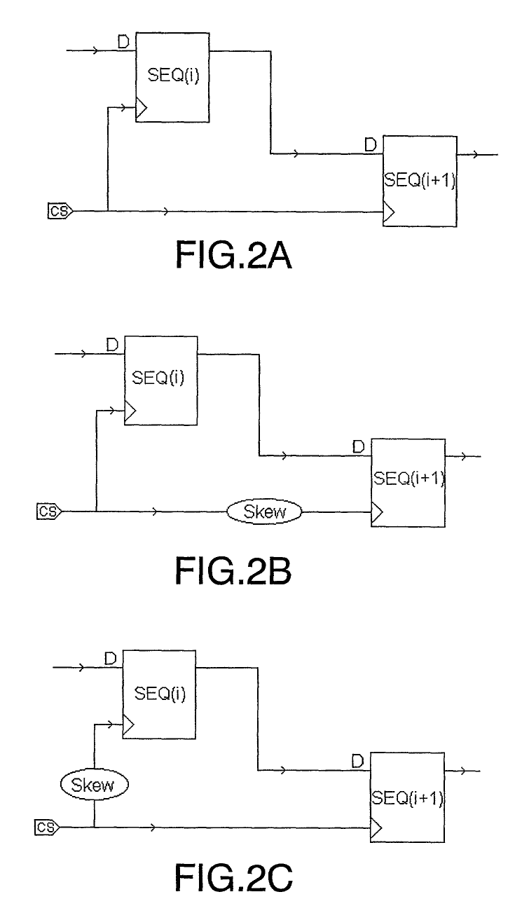

FIG. 2 is a diagram illustrating successive sequential cells in a series, in which:

FIG. 2A illustrates the case where there is no clock skew,

FIG. 2B illustrates the case where the driven cell has greater clock latency than the driving cell, and

FIG. 2C illustrates the case where the driving cell has greater clock latency than the driven cell;

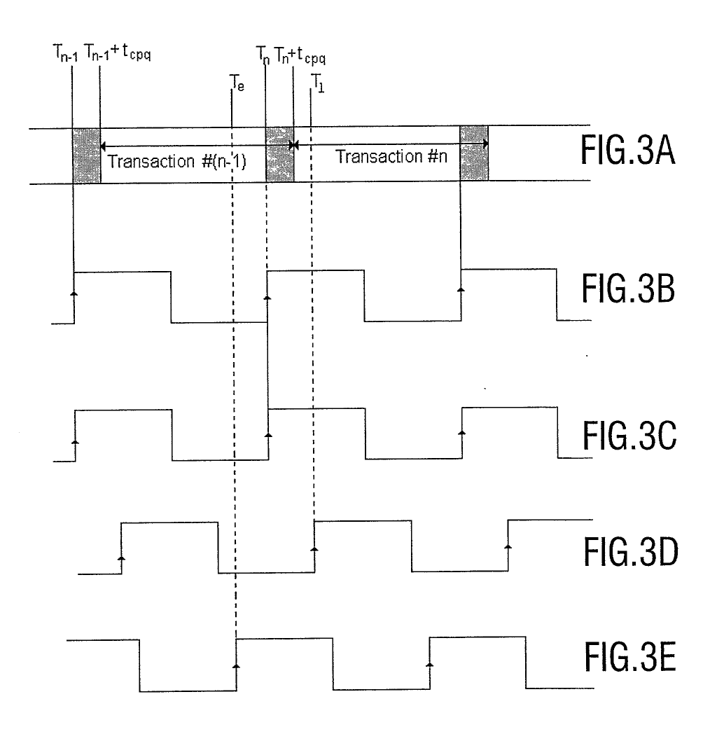

FIG. 3 shows timing diagrams for data shift transactions in the three cases of FIG. 2, in which:

FIG. 3A shows the timing of two successive transactions,

FIG. 3B shows the timing of the clock signal applied to the clock input of the driving cell in the three cases of FIG. 2,

FIG. 3C shows the timing of the clock signal applied to the clock input of the driven cell in the case of FIG. 2A,

FIG. 3D shows the timing of the clock signal applied to the clock input of the driven cell in the case of FIG. 2B,

FIG. 3E shows the timing of the clock signal applied to the clock input of the driven cell in the case of FIG. 2C;

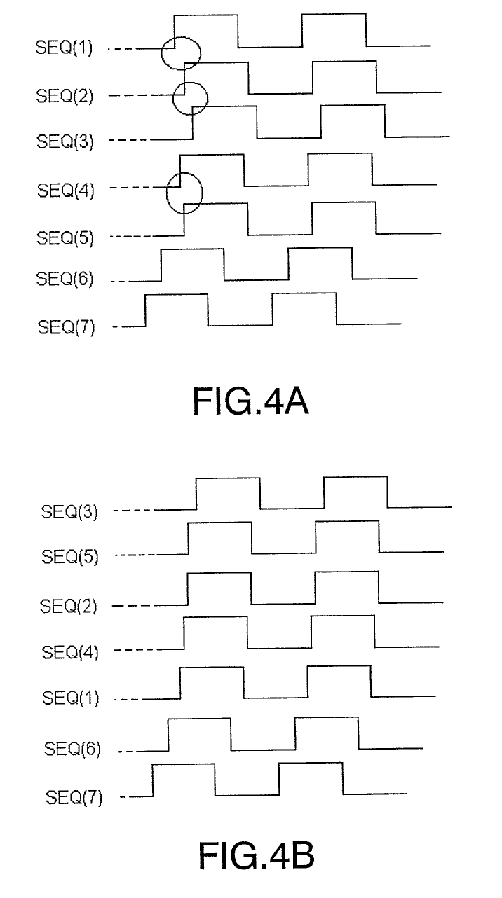

FIG. 4 shows timing diagrams of clock signals applied to 7 sequential cells in an example circuit, in which:

FIG. 4A shows timing diagrams for clock signals of 7 successive cells interconnected without reference to clock skew, and

FIG. 4B shows timing diagrams for clock signals of the same 7 cells when interconnected in an order that has been optimized with respect to clock skew; and

FIG. 5 schematically represents interconnections for two cells in a scan chain.

First some remarks will be made on the use of reference signs. Similar entities are denoted by an identical letter code throughout the drawings. Various similar entities may be shown in a single drawing. In that case, a numeral is added to the letter code so as to distinguish similar entities from each other. The numeral will be between parentheses if the number of similar entities is a running parameter. In the description and claims, any numeral in a reference sign may be omitted if appropriate.

As mentioned above, if the clock skew between successive sequential cells in a series implementing a shift is sufficiently great, then the shift operation will fail. This problem will be explained in greater detail with reference to FIG. 1, FIG. 2A, FIG. 2B, FIG. 3A, FIG. 3B and FIG. 3C.

FIG. 1 shows two cells, SEQ(i) and SEQ(j) in such a series. The clock path tⱼ from the clock source CS to the clock input CP of the cell SEQ(j) is longer than the clock path ti from the clock source CS to the clock input CP of the cell SEQ(i). Clock skew is defined as the absolute value of (tⱼ-tᵢ). In this example, the cells are implemented as D flip-flops. As is well-known, at each rising edge of the clock pulse applied to the clock input CP of the flip-flop, data present at the D input of the flip-flop is latched through to form the output Q. However, a short time period t_{cpq} is necessary in order for the data present at the D input to become available at the output Q. At the next rising edge of the clock pulse applied to the CP input, the next value of data at the D input is latched through, and will appear at the output Q a time period t_{cpq} later. In certain circumstances clock skew can lead to an attempt being made to shift data from a cell at a time when the desired data is not available at the Q output. In such circumstances the scan shift will fail.

Reference will now be made to FIG. 2A, FIG. 3A, FIG. 3B and FIG. 3C to explain normal shift and to FIG. 2B, FIG. 3A and FIG. 3D to explain a failed shift transaction caused by clock skew.

FIG. 2A illustrates the case of two successive cells, SEQ(i) and SEQ(i+1), in a series, with no clock skew. FIG. 3A illustrates the timing of two successive shift transactions (n−1 and n) in which data should be transferred from the driving cell SEQ(i) to the driven cell SEQ(i+1). FIG. 3B illustrates the timing of the clock signal applied to the CP input of the driving cell SEQ(i), whereas FIG. 3C illustrates the timing of the clock signal applied to the driven cell SEQ(i+1).

As can be seen from FIGS. 3B and 3C, because there is no clock skew in this case, the clock signals applied to the CP inputs of the driving cell and the driven cell are synchronized. At an instant Tₙ₋₁ there is a rising edge in the clock signal applied to the CP input of cell SEQ(i). Consequently, data at the D input of cell SEQ(i) is transferred to the Q output and is held during the interval (Tₙ₋₁+t_{cpq}) to (Tₙ+t_{cpq}). Thus, during the interval (Tₙ₋₁+t_{cpq}) to (Tₙ+t_{cpq}), the value of data D for the shift transaction number n−1 is available for transfer (shifting) further along the series of cells. The shift transaction can thus begin at or after Tₙ₋₁+t_{cpq}. In a similar way, the n^{th} shift transaction can begin at or after Tₙ+t_{cpq}, where Tₙ is the instant when the next rising edge occurs in the clock signal applied to the CP input of cell SEQ(i).

When a rising edge occurs in the clock signal applied to the driven cell SEQ(i+1), the data at the Q output of the driving cell SEQ(i) is fetched into the driven cell SEQ(i+1), via the D input thereof, and transferred to the Q output thereof. In this case, as shown in FIG. 3C, a rising edge occurs in the clock signal applied to the driven cell SEQ(i) at the instant Tₙ. At that instant Tn the output from driving cell SEQ(i) still corresponds to the value of the data applied to the D input of the driving cell SEQ(i) for transaction n−1. Thus, this value of the data is successfully shifted down the scan chain in transaction n−1.

By way of contrast, in the case illustrated in FIG. 2B, there is clock skew and the clock latency of the driven cell SEQ(i+1) is greater than that of the driving cell SEQ(i). As shown in FIG. 3D, this clock skew causes the driven cell SEQ(i+1) to receive a rising edge of the clock signal at its CP input at an instant T₁, which is too late for the data at the D input thereof still to correspond to the value of the data at the D input of the driving cell SEQ(i) at time Tₙ₋₁ . More particularly, at the instant T₁ the output of the driving cell corresponds to the value of the data applied to the D input of cell SEQ(i) at instant Tn, which is the data intended for the subsequent transaction. Consequently, incorrect data will be fetched into the driven cell SEQ(i+1) at this time and the integrity of the scan operation is compromised.

However, the present inventors have realized that, in the case where the clock latency of the driving cell is greater than that of the driven cell, clock skew can be benign. This positive effect of clock skew will be explained with reference to FIG. 2C, FIG. 3A and FIG. 3E.

FIG. 2C illustrates the case of clock skew where the driving cell SEQ(i) has greater clock latency than the driven cell SEQ(i+1). In this case, as shown in FIG. 3E, a rising edge occurs in the clock signal applied to the clock input of the driven cell SEQ(i+1) at an instant Tₑ. At this time, the Q output from the driving cell SEQ(i) is already equal to the value of the data applied at the D input thereof at time Tₙ₋₁. Therefore the driven cell SEQ(i+1) can fetch the value of this data early, and transaction n−1 is completed successfully.

In view of the above, the present inventors realized that clock skew need not be minimized if each clock skew within a series of sequential cells implementing a shift is such that the driving cells have greater clock latency than the driven cells. It is highly unlikely that this situation will arise by chance. Design of an integrated circuit including a series of sequential cells implementing a shift usually involves a number of steps. These steps typically include determination of the functions to be performed by the circuit, determination of the logic devices required to implement these functions, Place&Route and ClockTree generation functions.

The Place&Route function involves determination of the physical layout of the logic devices, and determination of the physical conductor paths that will interconnect them. The ClockTree generation function involves determination of the number and disposition of booster cells (or “repeater” cells) that are required in order to ensure that the clock signal has a sufficient amplitude when it arrives at each cell (bearing in mind that tens of thousands of cells may be involved). The ClockTree generation function usually also involves the insertion of buffer cells into the shortest clock paths, in order to reduce clock skew. The physical location of the buffer and repeater cells is usually also optimized in an attempt to minimize clock skew.

In some case, if calculations show that the remaining clock skew will cause problems hindering the shift operation, buffer cells may be inserted in the data transfer paths between selected sequential cells. New calculations are then performed to check whether the shift operation will be successful with the modified design. If the shift operation still has problems, then one or more further buffer cells may be inserted in the data transfer paths between the selected (or other) sequential cells, and the calculations repeated. Several iterations of these steps (“timing iterations”) may be necessary in order to optimize the design with respect to the shift operation.

The layout and interconnection of sequential cells resulting from the above-described steps will often involve one or more driven cells having a greater clock latency than the corresponding driving cells. According to the preferred embodiments of the present invention, at this stage in the design process, the following additional steps are performed:

determination of the clock latencies of the different cells in the series implementing a shift (according to the initial layout produced by earlier steps in the design process), and

setting the interconnections of these cells such that they are interconnected in order starting with the cell having the greatest clock latency and ending with the cell having the least clock latency.

The clock latencies of the different cells in the series depend upon the lengths of the respective conductors leading from the clock source to the cells in question and upon the buffer and repeater cells present in the respective clock paths. Thus, determination of the clock latencies involves calculations based on the initial physical layout of the circuit that has already been produced in the earlier steps of the design process.

Once the order in which the sequential cells should be interconnected has been decided, this conditions the paths that can be used for the conductors that will interconnect these cells. The paths are then set taking into account the practicalities of the IC manufacturing process.

In general, it is desired to minimize congestion on the integrated circuit substrate, that is, it is preferred to minimize the length of the conductors between the cells, where possible. It might be imagined that implementation of the technique according to the present invention would lead to an increase in congestion, due to the use of long conductors to interconnect the sequential cells in the appropriate order. Even if this were to be the case, a slight increase in the size of the substrate would solve the problem. However, it has been found that, in general, interconnecting the sequential cells in order of decreasing clock latency results in low congestion.

This can be understood when it is considered that cells which are physically located close together will generally have very similar clock latencies. Thus, for example, if the series of sequential cells included two rows of cells located respectively at the top and bottom edges of the substrate, the clock latencies of the top row would all be similar and the clock latencies of the cells in the bottom row would all be similar. Thus, when interconnecting the cells in order of decreasing clock latency, there would probably only be one long conductor interconnecting one cell of the bottom row with one cell of the top row, all of the other conductors would be short ones interconnecting cells of the same row.

Further, in a preferred embodiment of the present invention, if two cells have equal clock latency it is preferred to interconnect them in the series in the order which results in lowest congestion.

By applying the techniques according to the present invention, the resulting integrated circuit with series of sequential cells implementing a shift is not affected by clock skew problems. More particularly, it is ensured that shift transactions will be successful. Moreover, a low-congestion arrangement is produced.

Standard Layout and Test CAD tools (software) can be used for implementing the techniques of the present invention. Moreover, use of the techniques according to the invention makes it possible to eliminate the above-described timing iterations performed for shift-optimization purposes. This saves time during the design process, and reduces costs because fewer buffer cells are required. Also, in some cases, use of the techniques according to the present invention make it possible to simplify the ClockTree generation function by reducing the number of buffer cells inserted into the clock paths, or eliminating buffer cells altogether.

An example of application of the approach according to the present invention will now be given with reference to FIGS. 4A and 4B.

FIG. 4A shows the relative timings of clock signals that would be applied to the CP inputs of a sequence of 7 successive cells SEQ(1) to SEQ(7) in a particular arrangement implementing a shift, when the layout has not been optimized with respect to clock skew. It will be seen that this sequential cell layout would give rise to three hold violations during the shift operation (these are indicated by circles in FIG. 4A). In other words, according to this layout, the clock latency of cell SEQ(2) is greater than that of its driving cell SEQ(1), the clock latency of cell SEQ(3) is greater than that of its driving cell SEQ(2), and the clock latency of cell SEQ(5) is greater than that of its driving cell SEQ(4).

It will be seen from FIG. 4A that the clock latency is greatest for cell SEQ(3) and then decreases in the order SEQ(5), SEQ(2), SEQ(4), SEQ(1), SEQ(6), SEQ(7). Thus, according to the present invention, the arrangement can be optimized with respect to skew by interconnecting the cells in the order SEQ(3), SEQ(5), SEQ(2), SEQ(4), SEQ(1), SEQ(6), SEQ(7). FIG. 4B shows the relative timings of clock signals that would be applied to the CP inputs of the cells SEQ(1) to SEQ(7), when the cells have been interconnected in this order. It will be seen that there are no hold violations.

The above description relates to the present invention when applied in a generalized fashion to any series of sequential cells. The person skilled in this field will immediately appreciate how the techniques of the invention can be applied to specific series of sequential cells.

As an example, consider the case illustrated in FIG. 5, where the series of sequential cells corresponds to a scan chain. In such a case, as well as being involved in shifting test pattern data, each cell of the scan chain also takes part in the performance of the functions of the integrated circuit. Each cell, SEQ(i), SEQ(i+1), etc. has two multiplexed data inputs, one “functional” data input D, for inputting data involved in the performance of the IC functions, the other “non-functional” data input Dₜₑₛₜ, for inputting test pattern data being transferred along the scan chain. Each cell operates in “functional” or “non-functional” (i.e. scan) mode, according to the value of a control signal applied at an input CONT. Depending upon the operational mode of the cells (the value of the control signal), the data output from the cell's Q output is routed either to the IC's “functional” circuitry, or to the Dₜₑₛₜ input of the next cell in the scan chain.

The drawing and their description hereinbefore illustrate rather than limit the invention. It will be evident that there are numerous alternatives that fall within the scope of the appended claims. Any reference sign in a claim should not be construed as limiting the claim.

1. An integrated circuit comprising a series of sequential cells (SEQ), said series of sequential cells being adapted to implement a shift function, and a clock source (CS) for supplying a clock signal to said sequential cells, characterized in that the order in which the sequential cells are interconnected in said series depends upon the clock latencies thereof.

2. An integrated circuit according to claim 1, wherein the sequential cells (SEQ) are interconnected in order starting with the cell having greatest clock latency and ending with the cell having smallest clock latency.

3. An integrated circuit according to claim 1, wherein sequential cells having the same clock latency are interconnected in the order that minimizes congestion on the integrated circuit substrate.

4. An integrated circuit according to claim 1, wherein the series of sequential cells constitutes a scan chain adapted to shift test data.

5. A method of designing an integrated circuit including a series of sequential cells (SEQ), said series of sequential cells being adapted to implement a shift function, and a clock source (CS) for supplying a clock signal to said sequential cells, the method comprising the steps of:
determining an initial layout of the integrated circuit,
determining the clock latencies of the sequential cells (SEQ) based on said initial layout, and
setting the interconnections between the sequential cells (SEQ) such that the order of the sequential cells in said series depends upon the clock latencies thereof.

6. An integrated circuit design method according to claim 5, wherein the interconnection-setting step comprises setting the interconnections between the sequential cells (SEQ) such that the sequential cells are interconnected in order starting from the cell having greatest clock latency and ending with the cell having smallest clock latency.

7. An integrated circuit design method according to claim 5, wherein the interconnection-setting step comprises setting the interconnections between sequential cells having the same clock latencies such that the congestion on the integrated circuit substrate is minimized.

8. An integrated circuit design method according to claim 5, wherein the series of sequential cells constitutes a scan chain adapted to shift test data.
